(19) United States
(12) Patent Application Publication
(10) Pub. No.: US 2026/0215135 A1
(43) Pub. Date: Jul. 23, 2026

(54) DISPLAY DEVICE, METHOD OF MANUFACTURING THE SAME AND ELECTRONIC DEVICE INCLUDING THE SAME

(71) Applicant: SAMSUNG DISPLAY CO., LTD., YONGIN-SI (KR)

(72) Inventor: Jee Hoon PARK, Yongin-si (KR)

(21) Appl. No.: 19/447,137

(22) Filed: Jan. 13, 2026

(30) Foreign Application Priority Data
Jan. 22, 2025 (KR) 10-2025-0009456

(51) Int. Cl. H10K 59/80; H10K 50/115; H10K 59/12

(52) U.S. Cl. CPC H10K 59/873; H10K 50/115; H10K 59/1201

(57) ABSTRACT

A display device includes a base substrate. A plurality of transistors is arranged on the base substrate. A plurality of pixel electrodes is electrically connected to the plurality of transistors, respectively. A plurality of light-emitting portions is on the plurality of pixel electrodes, respectively. A counter electrode covers the plurality of light-emitting portions. A plurality of acid-containing patterns is disposed on the counter electrode and overlaps the plurality of light-emitting portions, respectively. The plurality of acid-containing patterns is spaced apart from each other.

### CROSS-REFERENCE TO RELATED APPLICATION AND CLAIM OF PRIORITY

This application claims priority under 35 U.S.C. § 119 to Korean Patent Application No. 10-2025-0009456, filed on Jan. 22, 2025 in the Korean Intellectual Property Office, the disclosure of which is incorporated by reference in its entirety herein.

### 1. TECHNICAL FIELD

Embodiments of the present disclosure relate to a display device, a method of manufacturing the same and an electronic device including the same.

### 2. DISCUSSION OF RELATED ART

Display devices in which quantum dots are used as a light-emitting material or a color conversion material have recently been developed. For example, a wavelength region of an emitted light may be controlled by adjusting a type and/or a size of the quantum dots.

The quantum dots have self-luminous properties and may provide increased color purity. However, quantum dots may exhibit a relatively short life-span and may have decreased luminous stability. Therefore, research is being conducted for achieving sufficient life-span and luminous stability from the quantum dots.

### SUMMARY

According to an aspect of embodiments of the present disclosure, there is provided a display device having increased luminous stability and life-span property.

According to an aspect of embodiments of the present disclosure, there is provided a method of manufacturing a display device having increased luminous stability and life-span property.

According to an aspect of embodiments of the present disclosure, there is provided an electronic device including a display device with increased luminous stability and life-span property.

According to an embodiment of the present disclosure, a display device includes a base substrate. A plurality of transistors is arranged on the base substrate. A plurality of pixel electrodes is electrically connected to the plurality of transistors, respectively. A plurality of light-emitting portions is on the plurality of pixel electrodes, respectively. A counter electrode covers the plurality of light-emitting portions. A plurality of acid-containing patterns is disposed on the counter electrode and overlaps the plurality of light-emitting portions, respectively. The plurality of acid-containing patterns is spaced apart from each other.

In some embodiments, the plurality of light-emitting portions may include quantum dots that emit different colors from each other.

In some embodiments, the plurality of transistors includes first to third transistors. The plurality of pixel electrodes includes first to third pixel electrodes. The plurality of light-emitting portions includes first to third light-emitting portions. The plurality of acid-containing patterns includes first to third acid-containing patterns. A thickness of the first acid-containing pattern may be different from a thickness of the second acid-containing pattern or the third acid-containing pattern or an acid component content of the first acid-containing pattern is different from acid component contents of the second acid-containing pattern and the third acid-containing pattern.

In some embodiments, the first light-emitting portion, the second light-emitting portion and the third light-emitting portion may include a blue light-emitting quantum dot, a green light-emitting quantum dot and a red light-emitting quantum dot, respectively.

In some embodiments, the thickness of the first acid-containing pattern may be greater than the thickness of each of the second acid-containing pattern and the third acid-containing pattern.

In some embodiments, the thickness of the second acid-containing pattern may be greater than the thickness of the third acid-containing pattern.

In some embodiments, the acid component content included in the first acid-containing pattern may be greater than the acid component content included in each of the second acid-containing pattern and the third acid-containing pattern.

In some embodiments, the acid component content included in the second acid-containing pattern may be greater than the acid component content included in the third acid-containing pattern.

In some embodiments, each of the plurality of light-emitting portions may include an emission layer including the quantum dots, and an electron transport layer between the emission layer and the counter electrode. The electron transport layer may include metal oxide particles including zinc.

In some embodiments, each of the plurality of acid-containing patterns includes at least one group selected from a carboxyl group, a sulfonic acid group and a phosphonic acid group.

In some embodiments, the plurality of acid-containing patterns is in direct contact with a top surface of the counter electrode.

In some embodiments, the display device may further include a protective layer stacked on the counter electrode. The plurality of acid-containing patterns may be in direct contact with a bottom surface of the protective layer facing the counter electrode, and are spaced apart from the counter electrode in a thickness direction of the display device.

According to an embodiment of the present disclosure, an electronic device may include a display device, a memory, and a processor executing data included in the memory to control an operation of the display device. The display device may include a base substrate. A plurality of transistors is arranged on the base substrate. A plurality of pixel electrodes is electrically connected to the plurality of transistors, respectively. A plurality of light-emitting portions is on the plurality of pixel electrodes, respectively. A counter electrode covers the plurality of light-emitting portions. A plurality of acid-containing patterns overlaps the plurality of light-emitting portions, respectively, and is separated from each other on the counter electrode.

In some embodiments, the electronic device may include virtual reality or augmented reality glasses, a smartphone, a tablet personal computer, a laptop personal computer, a television, a desk monitor, smart glasses, a head-mounted display, a smart watch, or a vehicle display.

According to an embodiment of the present disclosure, a method of manufacturing a display device includes forming a transistor array structure comprising a plurality of transistors. A plurality of pixel electrodes electrically connected to the plurality of transistors, respectively, is formed. A plurality of light-emitting portions is formed on the plurality of pixel electrodes, respectively. A counter electrode covering the plurality of light-emitting portions is formed. Acid-containing patterns are formed using a deposition mask that includes openings corresponding to the plurality of light-emitting portions on the counter electrode or a protective layer. The protective layer is stacked on the counter electrode with the acid-containing patterns interposed therebetween.

In some embodiments, in the formation of the acid-containing patterns, an acid-containing material may be deposited directly on the counter electrode.

In some embodiments, in the formation of the acid-containing patterns, an acid-containing material may be deposited directly on the protective layer.

In some embodiments, the deposition mask may include a fine metal mask (FMM).

In some embodiments, the forming of the transistor array structure comprises forming first to third transistors. The forming of the plurality of pixel electrodes comprises forming first to third pixel electrodes. The forming of the plurality of light-emitting portions comprises forming first to third light-emitting portions. The forming of the acid-containing patterns comprises forming a first acid-containing pattern, a second acid-containing pattern and a third acid-containing pattern overlapping the first light-emitting portion, the second light-emitting portion and the third light-emitting portion, respectively. The first to third acid-containing patterns are separated from each other. The first light-emitting portion, the second light-emitting portion and the third light-emitting portion include quantum dots that emit different colors from each other.

In some embodiments, in the formation of the acid-containing patterns, the first acid-containing pattern, the second acid-containing pattern and the third acid-containing pattern may be formed independently by shifting the deposition mask.

According to some embodiments of the present disclosure, an acid-containing pattern may be formed to correspond to each of light-emitting devices including quantum dots. Defect sites of a metal oxide included in an electron transport layer may be removed or reduced by using an acid generated from the acid-containing pattern. Thus, quantum efficiency and life-span stability of the light-emitting device or a display device including the quantum dots may be increased.

According to some embodiments of the present disclosure, the acid-containing pattern may be formed to have a composition/thickness for each pixel that enhances life-span/light-emission properties for each pixel.

### BRIEF DESCRIPTION OF THE DRAWINGS

FIG. 1 is a schematic plan view illustrating a display device according to an embodiment of the present disclosure.

FIG. 2 is a schematic cross-sectional view illustrating a display device according to an embodiment of the present disclosure.

FIG. 3 is a schematic cross-sectional view illustrating a display device according to an embodiment of the present disclosure.

FIG. 4 is a schematic cross-sectional view of a light-emitting device included in a display device according to an embodiment of the present disclosure.

FIG. 5 is a schematic cross-sectional view illustrating a display device according to an embodiment of the present disclosure.

FIG. 6 is a schematic cross-sectional view illustrating a display device according to an embodiment of the present disclosure.

FIG. 7 is a schematic cross-sectional view illustrating a display device according to an embodiment of the present disclosure.

FIGS. 8 to 10 are schematic views illustrating a method of manufacturing a display device according to some embodiments of the present disclosure.

FIGS. 11 to 14 are schematic views illustrating a method of manufacturing a display device according to some embodiments of the present disclosure.

FIG. 15 is a block diagram of an electronic device according to an embodiment of the present disclosure.

FIG. 16 is a schematic diagram of electronic devices according to an embodiment of the present disclosure.

### DETAILED DESCRIPTION OF EMBODIMENTS

Hereinafter, embodiments of the present disclosure will be described in more detail with reference to the attached drawings. The same reference numerals may be used for indicating the same elements in the drawings, and repeated descriptions of the same elements may be omitted for economy of explanation. Embodiments disclosed in the attached drawings are examples, and is to be understood to include all modifications, equivalents and substitutes included in the spirit and technical scope of the present disclosure.

The terms “on”, “connected”, “coupled,” etc., used herein refers to a direct placement/connection/combination, and also refers to a case where another element is interposed between two different elements. The terms “directly on”, “directly connected”, “directly coupled” refers to a case where no intervening elements are present.

The terms such as “first”, “second”, “below”, “lower”, “upper”, “above,” etc., are used in a relative sense to distinguish different elements or positions, and do not specify an absolute position or an absolute order.

The present disclosure concerns a display device comprising an emission layer having quantum dots in which an acid-containing pattern is disposed on a counter electrode or a protective layer. The acid-containing pattern may serve as an aging pattern that may enhance light emission efficiency. A thickness or acid component content of the acid-containing pattern included in one or more pixel regions may be greater than that included in other pixel regions. Therefore, quantum efficiency/light-emission efficiency by the inclusion of the acid-containing pattern may be increased according to pixel characteristics to increase the life span property of the display device.

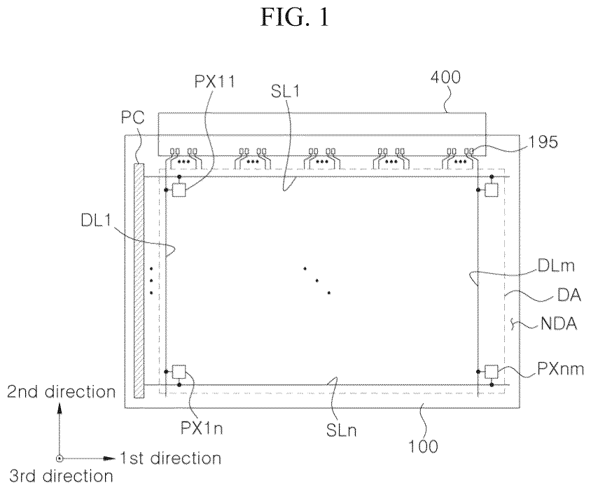

FIG. 1 is a schematic plan view of a display device according to an embodiment.

In FIG. 1, a first direction and a second direction may refer to two directions parallel to a top surface of a base substrate 100 and crossing each other at various different angles. For example, in an embodiment, the first direction and the second direction may be perpendicular to each other.

For example, the first direction may correspond to an X-direction (e.g., a row direction), and the second direction may correspond to a Y-direction (e.g., a column direction) of the display device.

A third direction may be perpendicular to the first direction and the second direction. The third direction may correspond to a Z-direction (e.g., a thickness direction) of the display device.

The definitions of the directions described above may be equally applied to the accompanying drawings.

Referring to FIG. 1, the display device may include a display area DA and a non-display area NDA. The display area AA may provide a surface on which an image of the display device is substantially implemented and a user's touch/command is input. The non-display area NDA may substantially correspond to a bezel area or a peripheral area of the display device. In an embodiment, the display area DA may be substantially surrounded by the non-display area NDA (e.g., in a plan view).

In an embodiment, the base substrate 100 may also be divided into the display area DA and the non-display area NDA. A plurality of pixels PX11 to PXnm may be arranged on the display area DA of the base substrate 100 in which n and m are an integer greater than or equal to 2.

According to some embodiments, a pixel circuit including scan lines (e.g., gate lines SL1 to SLn) forming first to n^{th} rows and data lines DL1 to DLm forming first to m^{th} columns may be arranged on a base substrate 100 of the display device. Each of the pixels PX11 to PXnm may be connected to (e.g., electrically connected thereto) a scan line of a corresponding row among a plurality of scan lines SL1 to SLn and a data line of a corresponding column among a plurality of data lines DL1 to DLm.

Each of the pixels PX11 to PXnm may further include a transistor and a light-emitting device as described below. In an embodiment, the pixel circuit may further include wirings such as a power line, a ground line, or the like.

In FIG. 1, data lines DL1 to DLm extend in the second direction, and scan lines SL1 to SLn extend in the first direction, but the present inventive concepts are not necessarily limited to the arrangement illustrated in FIG. 1.

A peripheral circuit PC may be disposed in the non-display area NDA corresponding to a peripheral area with respect to the display area DA. For example, the peripheral circuit PC may include a gate driving circuit. In an embodiment, the gate driving circuit may be integrated into the display device by an oxide semiconductor gate (OSG) driver circuit process, an amorphous silicon gate (ASG) driver circuit process, or a polysilicon gate (PSG) driver circuit process.

The peripheral circuit PC may further include a data driver, a gate driver, a light-emitting driver, a power voltage generator, a timing controller, or the like.

The display device may further include a printed circuit board 400. Pads 195 of the pixel circuit may be assembled on one side of the non-display area NDA. The printed circuit board 400 may be electrically connected to the pixel circuit through the pads 195. For example, in an embodiment, the printed circuit board 400 may be electrically connected to the pads 195 by a heat-compression process using a conductive intermediate structure such as an anisotropic conductive film (ACF).

In an embodiment, an integrated circuit (IC) such as a data driving circuit may be disposed on the printed circuit board 400. In some embodiments, an integrated circuit IC chip in the form of a chip-on-film (COF) may be mounted on the printed circuit board 400.

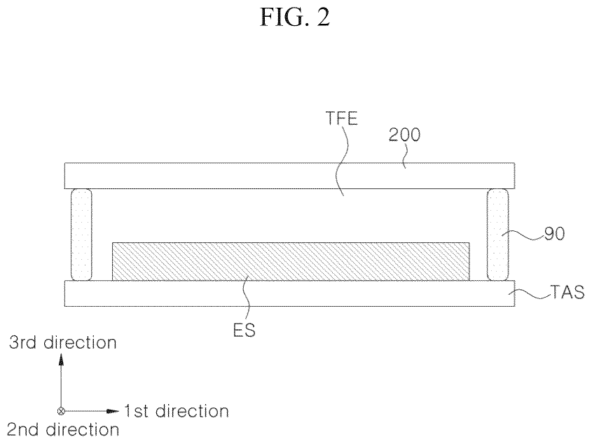

FIG. 2 is a schematic cross-sectional view illustrating a display device according to an embodiment.

Referring to FIG. 2, the display device may include a transistor array structure TAS and a light-emitting structure ES stacked on the transistor array structure TAS. The display device may further include a protective layer 200. The protective layer 200 may include at least one additional upper layer formed on an encapsulation layer TFE (e.g., formed directly thereon in the 3^{rd} direction). In an embodiment, the protective layer 200 may be provided as, an upper substrate or a protective substrate.

The protective layer 200 may face the transistor array structure TAS with the light-emitting structure ES interposed therebetween (e.g., in the 3^{rd} direction). The transistor array structure TAS may include a thin film transistor array (TFT-Array) substrate.

In an embodiment, the protective layer 200 and the transistor array structure TAS may be bonded or laminated to each other using a sealant 90. The sealant 90 may include a polymer material having elasticity. The sealant 90 may extend along the non-display area NDA of the base substrate 100.

The encapsulation layer TFE may be formed between the protective layer 200 and the transistor array structure TAS (e.g., in the 3^{rd} direction). The encapsulation layer TFE may cover the light-emitting structure ES on the transistor array structure TAS. The encapsulation layer TFE may be sealed by the sealant 90.

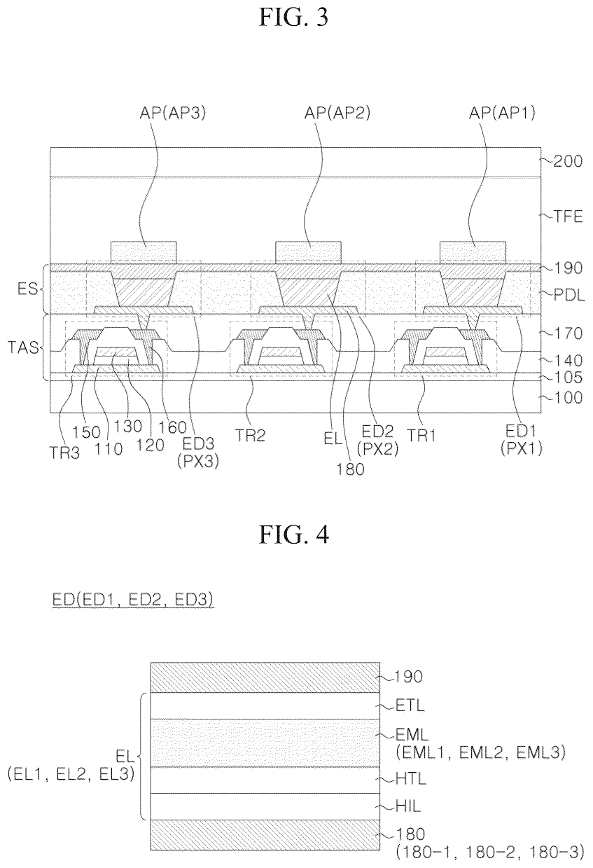

FIG. 3 is a schematic cross-sectional view illustrating a display device according to an embodiment.

Referring to FIG. 3, the display device may include the transistor array structure TAS and the light-emitting structure ES disposed on the transistor array structure TAS (e.g., disposed directly thereon in the 3^{rd} direction).

In an embodiment, the transistor array structure TAS may include the base substrate 100, and transistors TR1, TR2, and TR3 arranged on the base substrate 100. For example, the transistors may include first to third transistors TR1 to TR3. However, embodiments of the present disclosure are not necessarily limited thereto and the number of transistors may vary. The light-emitting structure ES may include a pixel defining layer PDL and a light-emitting device ED.

The base substrate 100 may be provided as a base substrate or a back-plane substrate of a display device. In an embodiment, the base substrate 100 may include a glass substrate, a ceramic substrate, or a plastic substrate. In some embodiments, the base substrate 100 may include a polymer material having transparency and flexibility. In this case, the base substrate 100 may be used in a transparent flexible, bendable or foldable display device.

For example, in an embodiment, the base substrate 100 may include a polymer material such as polyimide, polysiloxane, an epoxy resin, an acrylic resin, polyester, polyarylate, polycarbonate, polyethersulfone, polyphenylene sulfide, or the like. In an embodiment, the base substrate 100 may include polyimide.

A buffer layer 105 may be formed on a top surface of the base substrate 100 (e.g., disposed directly thereon in the 3^{rd} direction). In an embodiment, moisture penetrating through the base substrate 100 may be blocked by the buffer layer 105, and diffusion of impurities between structures formed on the base substrate 100 and the base substrate 100 may also be blocked by the buffer layer 105. The buffer layer 105 may be formed entirely over the display area DA and the non-display area NDA of the base substrate 100, and may entirely cover the top surface of the base substrate 100.

In an embodiment, the buffer layer 105 may include an inorganic insulating material such as silicon oxide, silicon nitride, and/or silicon oxynitride. These materials may be used alone or in a combination thereof. In some embodiments, the buffer layer 105 may have a stacked structure including a silicon oxide layer and a silicon nitride layer.

In an embodiment, the buffer layer 105 may be formed by a deposition process such as a chemical vapor deposition (CVD) process, a sputtering process, and an atomic layer deposition (ALD) process to include the inorganic insulating material.

The transistors TR1, TR2, and TR3 may be disposed on the buffer layer 105 (e.g., disposed directly thereon in the 3^{rd} direction). In an embodiment, the first transistor TR1, the second transistor TR2 and the third transistor TR3 may be electrically connected to a first light-emitting device ED1, a second light-emitting device ED2, and a third light-emitting device ED3, respectively.

Each of the first to third transistors TR1, TR2 and TR3 may include an active layer 110, a gate insulation layer 120 and a gate electrode 130. The first to third transistors TR1, TR2, and TR3 may be electrically connected to the first light-emitting device ED1 of a first pixel region PX1, a second light-emitting device ED2 of a second pixel region PX2, and the third light-emitting device ED3 of a third pixel region PX3, respectively. However, embodiments of the present disclosure are not necessarily limited thereto and the number of the pixel regions may vary in which at least some of the pixel regions emit light having a different color from light emitted by other pixel regions.

In an embodiment, the active layer 110 may be disposed on the buffer layer 105, and may be patterned by a photo-lithography process to be repeatedly/regularly arranged at each pixel. The active layer 110 may include a silicon compound such as polysilicon and amorphous silicon. A p-type dopant or an n-type dopant may be doped in a partial region of the active layer 110, so that the active layer 110 may include a source region, a drain region, and a channel region.

In an embodiment, the active layer 110 may include an oxide semiconductor such as indium gallium zinc oxide (IGZO), zinc tin oxide (ZTO), indium tin zinc oxide (ITZO), or the like.

The gate insulation layer 120 may be formed on the active layer 110, and the gate electrode 130 may be stacked on the gate insulation layer 120. As illustrated in FIG. 3, in an embodiment, the gate insulation layer 120 may be formed in a pattern shape partially covering each active layer 110.

However, embodiments of the present disclosure are not necessarily limited thereto. For example, in an embodiment, the gate insulation layer 120 may extend continuously over a plurality of the pixel regions PX1, PX2 and PX3, and may be commonly included in the first to third transistors TR1, TR2 and TR3.

The gate electrode 130 may overlap the channel region of the active layer 110 in the third direction.

In an embodiment, the gate insulation layer 120 may be formed by the above-described deposition process to include an inorganic insulating material such as silicon oxide, silicon nitride, silicon oxynitride, or the like. In some embodiments, the gate insulation layer 120 having a patterned shape may be formed as illustrated in FIG. 3 by a photo-lithography process in which the gate electrode 130 may be substantially used as an etching mask.

In some embodiments, the gate electrode 130 may be used as an ion implantation mask to inject impurities into the active layer 110. Accordingly, the source region and the drain region may be formed at one side portion and the other side portion of the active layer 110, respectively.

An insulating interlayer 140 covering the gate insulation layer 120 and the gate electrode 130 may be formed on the active layer 110. Connection electrodes 150 and 160 which are in direct contact with or electrically connected to the active layer 110 may be formed on the insulating interlayer 140.

In an embodiment, the insulating interlayer 140 may be formed through the above-described deposition process to include an inorganic insulating material such as silicon oxide, silicon nitride, silicon oxynitride, or the like. The insulating interlayer 140 may be formed in a single-layered structure or a multi-layered structure including different materials.

In some embodiments, when the active layer 110 includes an oxide semiconductor, hydrogen (H) included in the insulating interlayer 140 may be diffused or transferred to the active layer 110 when forming the insulating interlayer 140.

For example, hydrogen may be transferred to defect sites induced in the active layer 110 when etching the gate insulation layer 120. Accordingly, the source region and the drain region may be formed at the one side portion (e.g., a first side portion) and the other side portion (e.g., an opposite second side portion) of the active layer 110, respectively.

The connection electrodes 150 and 160 may penetrate the insulating interlayer 140 to be connected to (e.g., directly connected thereto) the active layer 110. In an embodiment in which the gate insulation layer 120 is continuously formed commonly in a plurality of the pixel regions, the connection electrodes 150 and 160 may also penetrate the gate insulation layer 120.

The connection electrodes 150 and 160 may include a source electrode 150 connected to or in direct contact with the source region of the active layer 110, and a drain electrode 160 connected to or in direct contact with the drain region of the active layer 110.

The contact holes may be formed by partially etching the insulating interlayer 140. For example, contact holes exposing the source region and the drain region, respectively, may be formed. In an embodiment in which the gate insulation layer 120 is formed as a continuous common layer for the first to third transistors TR1, TR2 and TR3, the contact holes may also penetrate the gate insulation layer 120.

In an embodiment, a metal layer filling the contact holes may be formed on the insulating interlayer 140, and the metal layer may be partially etched to form the source electrode 150 and the drain electrode 160.

In an embodiment, the gate electrode 130 and the connection electrodes 150 and 160 may include a metal such as Ag, Mg, Ca, Al, W, Cu, Ni, Cr, Mo, Ti, Pt, Ta, Nd, Sc, etc., an alloy thereof, or a nitride thereof. The gate electrode 130 and the connection electrodes 150 and 160 may be formed by the above-mentioned deposition process.

A planarization layer 170 covering the connection electrodes 150 and 160 may be formed on the insulating interlayer 140 (e.g., directly thereon in the 3^{rd} direction). The planarization layer 170 may accommodate a via structure electrically connecting the pixel electrode 180 and the drain electrode 160 to each other.

In some embodiments, the planarization layer 170 may include an organic material such as polyimide, an epoxy resin, an acrylic resin, polyester, a siloxane resin, a benzocyclobutene (BCB), or the like. In an embodiment, the planarization layer 170 may be formed by a coating process such as a spin coating process or the above-mentioned deposition process.

The pixel electrode 180 may include a plurality of pixel electrodes in which a pixel electrode 180 may be formed in each of the pixel regions, such as the first to third pixel regions PX1, PX2, and PX3, to be electrically connected to the transistors TR1, TR2, and TR3. The pixel electrode 180 may be formed on the planarization layer 170 to be electrically connected to the drain electrode 160.

For example, in an embodiment, the planarization layer 170 may be partially etched to form a via hole exposing a top surface of the drain electrode 160. A conductive layer including a metal or a transparent conductive oxide and filling the via hole may be formed on a top surface of the planarization layer 170, and then may be etched to form the pixel electrode 180.

The pixel electrode 180 may be provided as an anode and may include a high work function conductive material that may promote hole injection. The pixel electrode 180 may be formed as a transmissive electrode. In an embodiment, the pixel electrode 180 may include a transparent conductive oxide such as indium tin oxide (ITO), indium zinc oxide (IZO), zinc oxide (ZnO), and indium tin zinc oxide (ITZO).

The pixel electrode 180 may be formed as a translucent electrode or a reflective electrode. In an embodiment, the pixel electrode 180 may include a metal selected from Ag, Mg, Cu, Al, Pt, Pd, Au, Ni, Nd, Ir, Cr, Li, Ca, Li, Mo, Ti, W, In, Sn, and Zn, or an alloy or a compound (e.g., LiF) including at least one therefrom.

The pixel electrode 180 may have a single-layered structure or a multi-layered structure. For example, in an embodiment, the pixel electrode 180 may have a triple-layered structure of ITO/Ag/ITO.

A pixel defining layer PDL including openings exposing a top surface of the pixel electrode 180 may be formed on the planarization layer 170. The pixel regions PX1, PX2 and PX3 may be defined by a sidewall of the pixel defining layer PDL forming the openings of the pixel defining layer PDL. In an embodiment, a red pixel region having a red light-emitting quantum dot(s), a green pixel region having a green light-emitting quantum dot(s), and a blue pixel region having a blue light-emitting quantum dot(s) may be separated and defined by the pixel defining layer PDL.

According to an embodiment, the first pixel region PX1 may correspond to a blue pixel region, the second pixel region PX2 may correspond to a green pixel region, and the third pixel region PX3 may correspond to a red pixel region. The first light-emitting device ED1, the second light-emitting device ED2, and the third light-emitting device ED3 may correspond to a blue light-emitting device, a green light-emitting device, and a red-light emitting device, respectively. However, embodiments of the present disclosure are not necessarily limited thereto and the colors of the first to third pixel regions PX1 to PX3 and the corresponding light emitted by the first to third light-emitting devices ED1 to ED3 may vary.

In an embodiment, the pixel defining layer PDL may be formed by exposure and development processes after applying a photosensitive organic material such as a polysiloxane resin, a polyimide resin, or an acrylic resin. In some configurations, the pixel defining layer PDL may be formed by a printing process such as an inkjet printing process using a polymer material or an inorganic material.

A light-emitting portion EL may be disposed in each light-emitting region formed by the pixel defining layer PDL. According to an embodiment, the light-emitting portion EL may include an emission including quantum dots. For example, the light-emitting portion EL may be formed by a process such as a vacuum deposition, a spin coating, an inkjet printing, a laser printing, a casting, a laser thermal transfer, or the like. In an embodiment, the light-emitting portion EL may be formed by an inkjet printing.

A counter electrode 190 may be disposed on a top surface of the pixel defining layer PDL and the light-emitting portions EL (e.g., in the 3^{rd} direction). In an embodiment, the counter electrode 190 may be a common electrode that may be continuously and commonly provided in a plurality of the light-emitting regions or pixels. For example, in an embodiment, the counter electrode 190 may be commonly and continuously formed in a plurality of the pixel regions by a deposition process such as a sputtering process.

The counter electrode 190 may serve as an electron injection electrode or a cathode. In an embodiment, the counter electrode 190 may include a metal, an alloy, an electrically conductive compound, or the like, having a low work function.

For example, in an embodiment, the counter electrode 190 may include lithium (Li), silver (Ag), magnesium (Mg), silver-magnesium (Ag—Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These compounds may be used alone or in a combination thereof.

The counter electrode 190 may be formed as a transmissive electrode, a translucent electrode, or a reflective electrode. The counter electrode 190 may have a single-layered structure or a multi-layered structure.

The light-emitting devices, such as first to third light-emitting devices ED1, ED2, and ED3, may be defined by the above-described pixel electrode 180, the light-emitting portion EL, and the counter electrode 190. In an embodiment, the light-emitting devices ED1, ED2, and ED3 may be provided as a quantum dot electric field display (QED) device or a quantum dot light-emitting diode (QD-LED) display device. Constructions and structures of the light-emitting portion EL and the light-emitting device ED will be described in more detail with reference to FIG. 4.

According to an embodiment of the present inventive concept, an acid-containing pattern AP arranged corresponding to each pixel region may be formed on the counter electrode 190 (e.g., in the 3^{rd} direction). For example, in an embodiment, the acid-containing pattern AP may be disposed directly on a top surface of the counter electrode 190. In an embodiment, the acid-containing pattern AP may include a first acid-containing pattern AP1 overlapping the first pixel region PX1, a second acid-containing pattern AP2 overlapping the second pixel region PX2, and a third acid-containing pattern AP3 overlapping the third pixel region PX3. However, embodiments of the present disclosure are not necessarily limited thereto and the number of the acid-containing patterns and the corresponding pixel regions may vary.

A plurality of the first acid-containing patterns AP1 may correspond to each of the first pixel regions PX1, and may cover (e.g., be disposed directly thereon in the 3^{rd} direction) each of the first light-emitting devices ED1. A plurality of the second acid-containing patterns AP2 may correspond to each of the second pixel regions PX2, and may cover (e.g., be disposed directly thereon in the 3rd direction) each of the second light-emitting devices ED2. A plurality of the third acid-containing patterns AP3 may correspond to each of the third pixel regions PX3, and may cover (e.g., be disposed directly thereon in the 3rd direction) each of the third light-emitting devices ED3.

In an embodiment, the first to third acid-containing patterns AP1, AP2, and AP3 may be independently separated from each other (e.g., completely spaced apart from each other in a plan view) to have island pattern shapes covering the pixel regions PX1, PX2, and PX3, respectively. In an embodiment, the first to third acid-containing patterns AP1, AP2, and AP3 may be in direct contact with a top surface of the counter electrode 190, and may partially cover the top surface of the counter electrode 190, such as a surface overlapping the opening in the pixel defining layer PDL.

According to an embodiment of the present disclosure, the acid-containing pattern AP may include an acid-containing material. In some embodiments, the acid-containing pattern AP may include an acid-containing organic material or a polymer acid material.

In some embodiments, the acid-containing pattern AP may include a polymer material including a carboxyl group (COOH), a phosphonic acid group (PO(OH)₂), a sulfonic acid group (SO₃H), or a combination thereof. For example, in an embodiment, the acid-containing pattern AP may include at least one compound selected from polyacrylic acid, polymethacrylic acid, polyacrylic acid-methacrylic acid, a copolymer including a (meth)acrylic acid repeating unit, polyvinyl phosphonic acid, polyvinyl sulfonic acid, polymaleic acid, and the like.

The acid-containing pattern AP may serve as an aging pattern. According to an embodiment, the acid-containing pattern AP may provide a proton (H+) to induce a positive aging of the light-emitting portion EL included in the light-emitting device ED to increase light emission efficiency.

For example, acid components (H+) and moisture contained in an acid-containing material contained in the acid-containing pattern AP may passivate defects on a surface of nanoparticles in the light-emitting portion EL.

According to an embodiment, the acid components and moisture contained in the acid-containing pattern AP may pass through the counter electrode 190 to induce a surface chemical reaction of metal oxide nanoparticles (e.g., ZnMgO) in an electron transport layer ETL (see FIG. 4).

Accordingly, a trap site may be removed or reduced while curing defects on the surface of the metal oxide nanoparticles. Accordingly, hole blocking properties of the metal oxide nanoparticles may be increased, and hole-electron combination may be promoted.

According to an embodiment, a content of the acid component included in the first acid-containing pattern AP1 formed on the first pixel region PX1 corresponding to the blue pixel region or the first light-emitting device ED1 may be greater than a content of the acid component included in each of the second acid-containing pattern AP2 and the third acid-containing pattern AP3.

The content of the acid component may refer to an amount of acidic units contained in the acid-containing pattern (AP). In an embodiment, the acidic unit may be at least one group selected from a carboxyl group, a sulfonic acid group, and a phosphonic acid group.

In an embodiment, the contents of the acid component included in the second acid-containing pattern AP2 covering the second pixel region PX2 (e.g., the second light-emitting device ED2) corresponding to the green pixel region, and the third acid-containing pattern AP3 covering the third pixel region PX3 (e.g., the third light-emitting device ED3) corresponding to the red pixel region may be substantially the same as or similar to each other.

In some embodiments, the content of the acid component included in the second acid-containing pattern AP2 may be greater than the content of the acid component included in the third acid-containing pattern AP3.

According to an embodiment, the above-described acid-induced positive aging effect in the blue pixel region may be greater than that in the red pixel region and the green pixel region, as will be described in more detail in Experimental Example. Accordingly, quantum efficiency/light-emission efficiency by the formation of the acid-containing pattern AP may be adjusted according to pixel characteristics by relatively increasing the content of the acid component included in the first acid-containing pattern AP1.

In some embodiments, the above-described acid-induced positive aging effect in the green pixel region may be greater than that in the red pixel region. In this embodiment, the content of the acid component included in the second acid-containing pattern AP2 may be increased relatively to the content of the acid component included in the third acid-containing pattern AP3.

In some embodiments, the first, second and third acid-containing patterns AP1, AP2 and AP3 may have substantially the same thickness as each other. In this case, as described above, the acid-induced positive aging effect suitable for each pixel may be implemented by adjusting the content of the acid component included in the first, second and third acid-containing patterns AP1, AP2 and AP3.

An encapsulation layer TFE may be formed on the counter electrode 190 (e.g., disposed directly thereon in the 3^{rd} direction). The encapsulation layer TFE may cover the pixel defining layer PDL, the light-emitting devices ED1, ED2 and ED3, and the acid-containing patterns AP to protect the light-emitting devices ED1, ED2 and ED3 from moisture or oxygen.

In an embodiment, the encapsulation layer TFE may include an inorganic layer including silicon nitride (SiNx), silicon oxide (SiOx), indium tin oxide, indium zinc oxide, or any combination thereof, an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)), or any combination thereof; or a combination of the inorganic and organic layers.

The encapsulation layer TFE may be formed in a single-layered structure or a multi-layered structure. In some embodiments, the encapsulation layer TFE may have a sequentially stacked structure of a first inorganic layer, an organic layer, and a second inorganic layer. However, embodiments of the present disclosure are not necessarily limited thereto.

In some embodiments, the encapsulation layer TFE may further include an overcoating layer. The overcoating layer may serve as a sealing layer for laminating the protective layer 200 and the light-emitting structure ES. In an embodiment, the overcoating layer may include a resin material such as an acrylic resin, an epoxy resin, an imide resin, or the like.

The protective layer 200 may include a glass substrate or a transparent plastic substrate.

FIG. 4 is a schematic cross-sectional view of a light-emitting device included in a display device according to an embodiment.

Referring to FIG. 4, in an embodiment, the light-emitting device ED may include the light-emitting portion EL disposed between the pixel electrode 180 and the counter electrode 190 (e.g., in the 3^{rd} direction). In an embodiment, the light-emitting portion EL may include a hole transport layer HTL, an emission layer EML, and an electron transport layer ETL. According to an embodiment, the hole transport layer HTL, the emission layer EML, the electron transport layer ETL, and the counter electrode 190 may be sequentially stacked (e.g., in the 3^{rd} direction) from a top surface of the pixel electrode 180. In some embodiments, a hole injection layer HIL may be further formed between the hole transport layer HTL and the pixel electrode 180 (e.g., in the 3^{rd} direction).

In an embodiment, the hole transport layer HTL may include a hole transporting material such as m-MTDATA (4,4′,4″-[tris(3-methylphenyl)phenylamino]triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

According to an embodiment, the electron transport layer ETL may include metal oxide particles (e.g., metal oxide nanoparticles). The metal oxide particles may include zinc oxide. In an embodiment, the zinc oxide may further include a metal such as an alkali metal, an alkaline earth metal, Zr, W, Li, Ti, Y, Al, Ga, In, and V in addition to zinc (Zn).

In some embodiments, the metal oxide particles may further include Mg, Ca, Zr, W, Li, Ti, Y, Al, or a combination thereof in addition to zinc. In an embodiment, the metal oxide particles may include zinc-magnesium oxide (ZnMgO).

The first light-emitting device ED1 may include a first light-emitting portion EL1 including a first emission layer EML1. The second light-emitting device ED2 may include the second light-emitting portion EL2 including a second emission layer EML2. The third light-emitting device ED3 may include a third light-emitting portion EL3 including a third emission layer EML3.

The first light-emitting portion EL1, the second light-emitting portion EL2, and the third light-emitting portion EL3 may be disposed on a first pixel electrode 180-1, a second pixel electrode 180-2, and a third pixel electrode 180-3, respectively (e.g., in the 3^{rd} direction). The first pixel electrode 180-1, the second pixel electrode 180-2, and the third pixel electrode 180-3 may be electrically connected to the first transistor TR1, the second transistor TR2, and the third transistor TR3, respectively.

According to an embodiment of the present disclosure, the emission layer EML may include quantum dots. In an embodiment, the quantum dot may include a group II-VI compound, a group III-VI compound, a group I-III-VI compound, a group III-V compound, a group III-II-V compound, a group IV-VI compound, a group IV element, a group IV compound, or a combination thereof.

The quantum dot may include a core including the above-described compound and may include a shell surrounding the core. The shell may include an inorganic oxide or a semiconductor compound. In an embodiment, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like.

The quantum dots may be surface-treated with an organic ligand and/or a halogen element.

A color of an emitted light may be adjusted according to a particle size of the quantum dots. For example, in an embodiment, the quantum dots may be classified into blue quantum dots, red quantum dots, and green quantum dots.

For example, a blue light having a central wavelength in a range from 420 nm to 480 nm may be generated from the blue quantum dot. A green light having a central wavelength in a range from 500 nm to 580 nm may be generated from the green quantum dot. A red light having a central wavelength in a range from 600 nm to 670 nm may be generated from the red quantum dot.

According to an embodiment, the first emission layer EML1, the second emission layer EML2 and the third emission layer EML3 may include the blue quantum dot, the green quantum dot and the red quantum dot, respectively.

In an embodiment, the hole injection layer HIL may include the above-described hole transport material, a p-type metal oxide (e.g., NiO, WO₃, MoO₃, or the like), and a carbon-based material such as graphene oxide.

In some embodiments, an electron injection layer may be further formed between the counter electrode 190 and the electron transport layer ETL (e.g., in the 3^{rd} direction). The electron injection layer may include the above-mentioned metal oxide nanoparticles. For example, in an embodiment, the electron injection layer may include zinc oxide or zinc-magnesium oxide.

Each of the above-described layers included in the light-emitting portion EL may be selectively patterned within each pixel region defined by a sidewall forming an opening of the pixel defining layer PDL through a printing process such as an inkjet printing.

In some embodiments, the hole transport layer HTL (or the hole injection layer HIL) and the electron transport layer ETL (or the electron injection layer) may be formed as common layers continuously provided in the first to third pixel regions PX1, PX2 and PX3, and the emission layer EML may be selectively patterned within each pixel region.

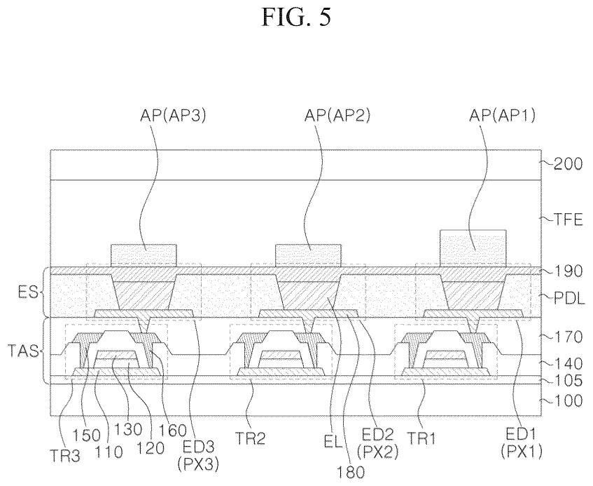

FIGS. 5 to 7 are schematic cross-sectional view illustrating display devices according to some embodiments. Detailed descriptions on elements, structures and materials substantially the same as or similar to those described with reference to FIGS. 3 and 4 are omitted for economy of explanation.

Referring to FIG. 5, in an embodiment, a thickness (e.g., length in the 3^{rd} direction) of the first acid-containing pattern AP1 corresponding to the first pixel region that may be the blue pixel region may be greater than a thickness (e.g., length in the 3^{rd} direction) of each of the second acid-containing pattern AP2 and the third acid-containing pattern AP3.

In some embodiments, the first to third acid-containing patterns AP1, AP2 and AP3 may be formed using the same acid-containing material (e.g., having a same acid component content as each other). In this case, the thickness of the first acid-containing pattern AP1 may be relatively increased to sufficiently induce an acid-induced positive aging effect in the blue pixel region.

In an embodiment, the thicknesses (e.g., lengths in the 3^{rd} direction) of the second acid-containing pattern AP2 and the third acid-containing pattern AP3 may be substantially the same as each other. In an embodiment, the thickness (e.g., length in the 3^{rd} direction) of the second acid-containing pattern AP2 may be greater than the thickness (e.g., length in the 3^{rd} direction) of the third acid-containing pattern AP3, and may be less than the thickness of the first acid-containing pattern AP1.

However, embodiments of the present disclosure are not necessarily limited thereto and, in some embodiments, a different number of light-emitting portions than the first to third light-emitting portions EL1 to EL3 are included in the display device and the display device includes a corresponding number of acid-containing patterns in which one or more of the acid-containing patterns have an increased content of the acid component or increased thickness so that the quantum efficiency/light-emission efficiency may be effectively arranged according to pixel characteristics. In some embodiments, one or more of the acid-containing patterns may have both an increased thickness and an increased acid component content.

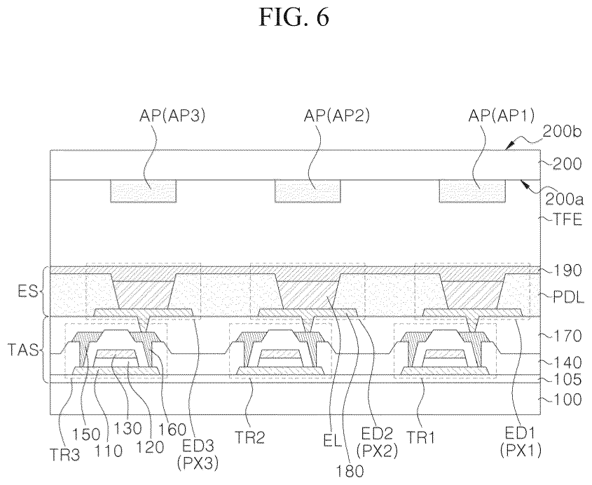

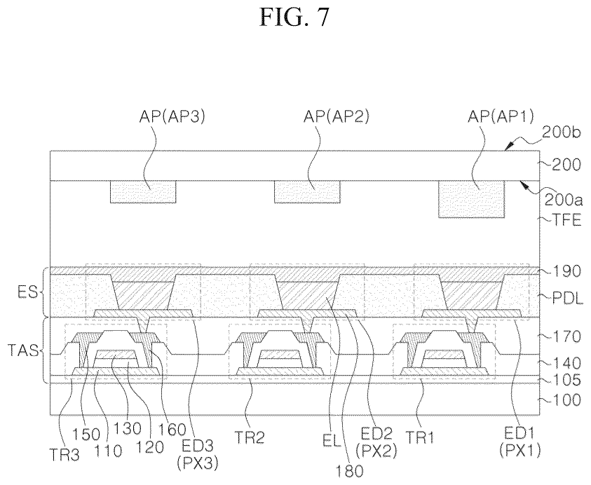

Referring to FIGS. 6 and 7, the acid-containing patterns AP may be spaced apart from the light-emitting structure ES, such as the counter electrode 190 (e.g., in the 3^{rd} direction), and may be formed on the protective layer 200 (e.g., formed directly thereon in a direction opposite to the 3^{rd} direction).

The protective layer 200 may include a first surface 200a and a second surface 200b facing each other (e.g., in the 3^{rd} direction). The first surface 200a and the second surface 200b may correspond to a bottom surface and a top surface of the protective layer 200, respectively. The first surface 200a may correspond to an inner surface facing the light-emitting structure ES, and the second surface 200b may correspond to an outer surface of the display device. In an embodiment, the acid-containing patterns AP may be disposed directly on the first surface 200a (e.g., the bottom surface) of the protective layer 200.

In an embodiment, a plurality of the first acid-containing patterns AP1, a plurality of the second acid-containing patterns AP2, and a plurality of the third acid-containing patterns AP3 may be arranged in the form of island patterns spaced apart from each other (e.g., in a plan view) on the first surface 200a of the protective layer 200.

The first acid-containing patterns AP1 may overlap the first pixel regions PX1 (e.g., the first light-emitting devices ED1) with the encapsulation layer TFE interposed therebetween (e.g., in the 3^{rd} direction). The second acid-containing patterns AP2 may overlap the second pixel regions PX2 (e.g., the second light-emitting devices ED2) with the encapsulation layer TFE interposed therebetween (e.g., in the 3^{rd} direction). The third acid-containing patterns AP3 may overlap the third pixel regions PX3 (e.g., the third light-emitting devices ED3) with the encapsulation layer TFE interposed therebetween (e.g., in the 3^{rd} direction).

In some embodiments, the first acid-containing pattern AP1, the second acid-containing pattern AP2 and the third acid-containing pattern AP3 may have substantially the same thickness as each other (e.g., length in the 3^{rd} direction). In this case, a content of the acid component included in the first acid-containing pattern AP1 may be greater than a content of the acid component included in each of the second acid-containing pattern AP2 and the third acid-containing pattern AP3. In an embodiment, the content of the acid component included in the second acid-containing pattern AP2 may be greater than the content of the acid component included in the third acid-containing pattern AP3.

In some embodiments, as illustrated in FIG. 7, the thickness (e.g., length in the 3^{rd} direction) of the first acid-containing pattern AP1 may be greater than the thicknesses (e.g., length(s) in the 3^{rd} direction) of each of the second acid-containing pattern AP2 and the third acid-containing pattern AP3. In an embodiment, the thickness of the second acid-containing pattern AP2 may be greater than the thickness of the third acid-containing pattern AP3.

In some embodiments, the first acid-containing pattern AP1, the second acid-containing pattern AP2, and the third acid-containing pattern AP3 may be formed using substantially the same acid-containing material, and the acid-induced positive aging effect may be adjusted through the above-described thickness adjustment for each pixel region.

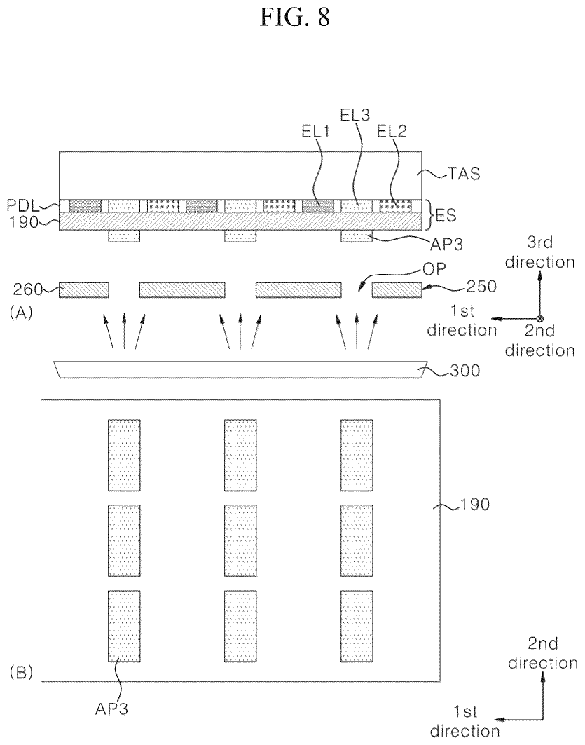

FIGS. 8 to 10 are schematic views illustrating a method of manufacturing a display device according to some embodiments. FIGS. 8 to 10 are schematic views illustrating a method of manufacturing the display device illustrated in FIG. 3 or 5. Parts (A) of FIGS. 8 to 10 are cross-sectional view schematically illustrating the acid-containing pattern forming process, and parts (B) are plan views illustrating a shape in which the acid-containing patterns are formed.

For convenience of description, detailed illustrations of elements and structures included in the transistor array structure TAS and the light-emitting device ED are omitted in FIGS. 8 to 10.

Referring to FIG. 8, as described with reference to FIG. 3, the light-emitting structure ES may be formed on the transistor array structure TAS. In an embodiment, the light-emitting structure ES may include the first to third light-emitting portions EL1, EL2 and EL3 formed in the first to third pixel regions PX1, PX2 and PX3, respectively, defined by openings in the pixel defining layer PDL and on the pixel defining layer PDL. Thereafter, the counter electrode 190 that may commonly cover the pixel defining layer PDL and the first to third light-emitting portions EL1, EL2 and EL3 may be formed.

Thereafter, the counter electrode 190 may be aligned towards a deposition mask 250. In an embodiment, a fine metal mask (FMM) may be used as the deposition mask 250. For example, in an embodiment, the deposition mask 250 may include a mask body 260 including an invar alloy, and may include an opening OP corresponding to each pixel region penetrating the mask body 260.

The deposition mask 250 may be aligned such that the openings OP may correspond to the third pixel region PX3 (e.g., the third light-emitting portions EL3). A deposition apparatus 300 may be positioned under the deposition mask 250, and a deposition source may be injected through the openings OP to form third acid-containing patterns AP3 overlapping the third light-emitting portions EL3.

The deposition source may include the acid-containing material as described above. For example, in an embodiment the acid-containing material may be dissolved in an organic solvent to form an aging composition. In some embodiments, the aging composition may further include a cross-linkable compound or a cross-linkable resin for promoting the formation of the acid-containing pattern.

In an embodiment, the aging composition may be vaporized or converted into plasma through the deposition apparatus 300 to pass through the opening OP. Accordingly, the third acid-containing pattern AP3 may be formed on the counter electrode 190 (e.g., formed directly thereon) to overlap the third light-emitting portion EL3 substantially overlapping the opening OP.

As illustrated in (B) of FIG. 8, in an embodiment, a plurality of the third acid-containing patterns AP3 may be formed on the counter electrode 190 along the second direction to form a third acid-containing pattern column. A plurality of the third acid-containing pattern columns may be formed along the first direction.

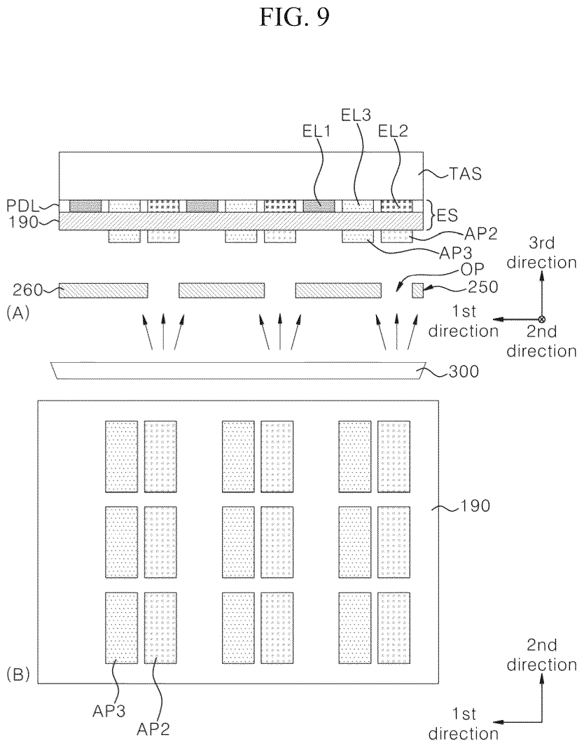

Referring to FIG. 9, the deposition mask 250 may be shifted to align the openings OP with the second pixel region PX2 (e.g., the second light-emitting portion EL2).

Thereafter, as described above, the aging composition may be vaporized or converted into plasma through the deposition apparatus 300 to deposit the acid-containing material. Accordingly, the second acid-containing pattern AP2 may be formed on the counter electrode 190 (e.g., formed directly thereon) to overlap the second light-emitting portion EL2.

As illustrated in (B) of FIG. 9, in an embodiment, a plurality of the second acid-containing patterns AP2 may be formed on the counter electrode 190 along the second direction to form a second acid-containing pattern column. A plurality of the second acid-containing pattern columns may be formed along the first direction. For example, the second acid-containing pattern columns may be formed between the third acid-containing pattern columns.

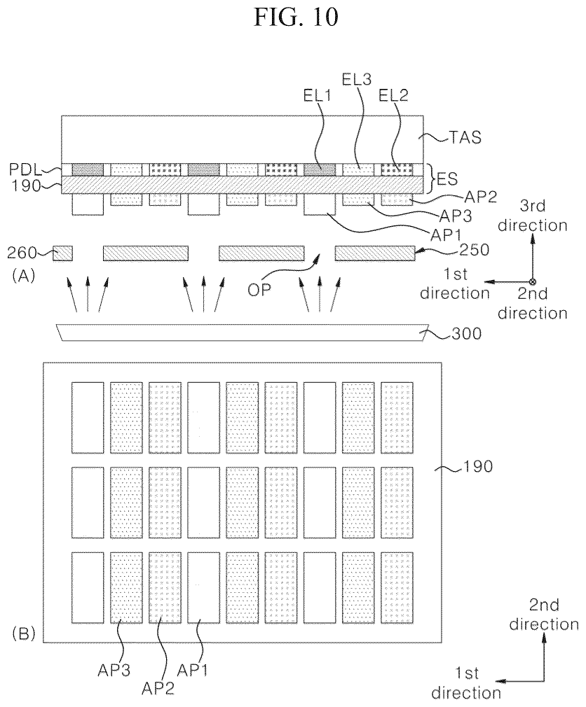

Referring to FIG. 10, the deposition mask 250 may be shifted to align the openings OP with the first pixel region PX1 (e.g., the first light-emitting portion EL1).

Thereafter, as described above, the acid-containing material may be deposited by vaporizing the aging composition or forming plasma from the aging composition through the deposition apparatus 300. Accordingly, the first acid-containing pattern AP1 may be formed on the counter electrode 190 (e.g., formed directly thereon) to overlap the first light-emitting portion EL1.

As illustrated in (B) of FIG. 10, in an embodiment, a plurality of the first acid-containing patterns AP1 may be formed on the counter electrode 190 along the second direction to form a first acid-containing pattern column. A plurality of the first acid-containing pattern columns may be formed along the first direction. For example, the first acid-containing pattern column may be formed between the second acid-containing pattern column and the third acid-containing pattern column adjacent to each other.

In some embodiments, when forming the first acid-containing pattern AP1, a deposition time or a supply flow rate of the deposition source may be increased to relatively increase the thickness of the first acid-containing pattern AP1 (e.g., length in the 3^{rd} direction). In some embodiments, the content of the acid-containing material or the acid component in the aging composition for forming the first acid-containing pattern AP1 may be relatively increased. In this case, even when the thickness of the first acid-containing pattern AP1 is the same as that of the second and third acid-containing patterns AP2 and AP3, the content of the acid component may be relatively increased. However, embodiments of the present disclosure are not necessarily limited thereto. In some embodiments, the method of manufacturing a display device includes forming a different number of light-emitting portions and a corresponding number of acid-containing patterns in which one or more of the acid-containing patterns have an increased content of the acid component or increased thickness so that the quantum efficiency/light-emission efficiency may be effectively arranged according to pixel characteristics.

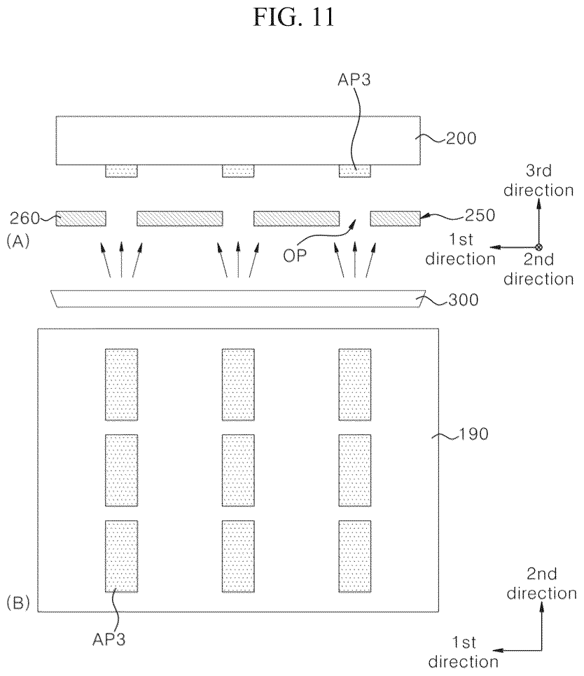

In FIGS. 8 to 10, the third acid-containing pattern AP3, the second acid-containing pattern AP2, and the first acid-containing pattern AP1 are sequentially formed, but the order of formation of the acid-containing patterns AP1, AP2 and AP3 is not necessarily limited thereto and may vary in which each of the first to third acid-containing patterns AP1 to AP3 are formed independently by shifting the deposition mask 250 (FIG. 11).

Referring back to FIG. 3, the encapsulation layer TFE covering the acid-containing patterns AP and the counter electrode 190 may be formed. Thereafter, in an embodiment, the protective layer 200 may be laminated or stacked on the encapsulation layer TFE using the sealant 90 (see FIG. 2).

FIGS. 11 to 14 are schematic views illustrating a method of manufacturing a display device according to some embodiments. FIGS. 11 to 14 are schematic views illustrating a method of manufacturing the display device illustrated in FIG. 6 or 7. Parts (A) of FIGS. 11 to 14 are cross-sectional views schematically illustrating an acid-containing pattern forming process, and parts (B) of FIGS. 11 to 14 are plan views illustrating a shape in which the acid-containing patterns are formed.

For convenience of description, detailed illustrations of elements and structures included in the transistor array structure TAS and the light-emitting device ED are omitted in FIGS. 11 to 14.

Referring to FIG. 11, the protective layer 200 may be prepared. The first surface 200a (see FIG. 6) of the protective layer 200 may be positioned over the deposition mask 250. The openings OP of the deposition mask 250 may be aligned under regions of the first surface 200a of the protective layer 200 corresponding to or overlapping the third pixel region PX3 (e.g., the third light-emitting portion EL3).

Thereafter, the third acid-containing patterns AP3 may be formed on (e.g., formed directly thereon) the first surface 200a of the protective layer 200 by performing a process substantially the same as or similar to that described with reference to FIG. 8.

As illustrated in (B) of FIG. 11, in an embodiment, a plurality of the third acid-containing patterns AP3 may be formed on the protective layer 200 along the second direction to form a third acid-containing pattern column. A plurality of the third acid-containing pattern columns may be formed along the first direction.

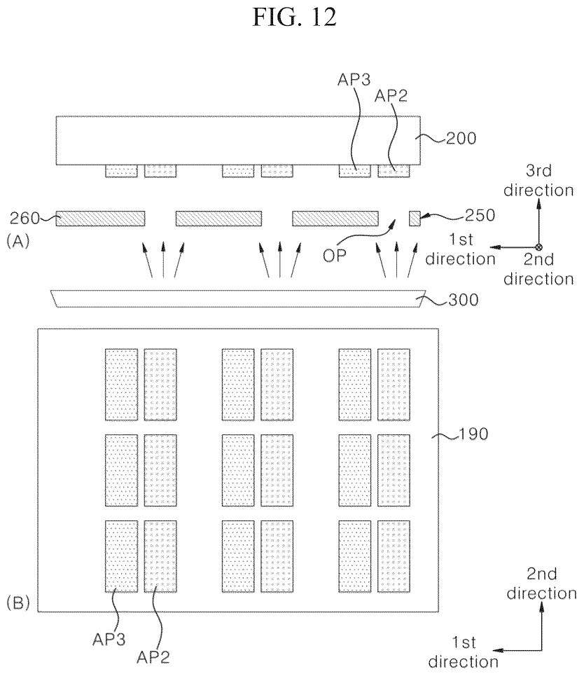

Referring to FIG. 12, the deposition mask 250 may be shifted to align the openings OP under regions of the first surface 200a of the protective layer 200 corresponding to or overlapping the second pixel region PX2 (e.g., the second light-emitting portion EL2).

Thereafter, the second acid-containing patterns AP2 may be formed on the first surface 200a of the protective layer 200 by performing a process substantially the same as or similar to that described with reference to FIG. 9.

As illustrated in (B) of FIG. 12, in an embodiment, a plurality of the second acid-containing patterns AP2 may be formed on (e.g., formed directly thereon) the protective layer 200 along the second direction to form a second acid-containing pattern column. A plurality of the second acid-containing pattern columns may be formed along the first direction. For example, the second acid-containing pattern columns may be formed between the third acid-containing pattern columns.

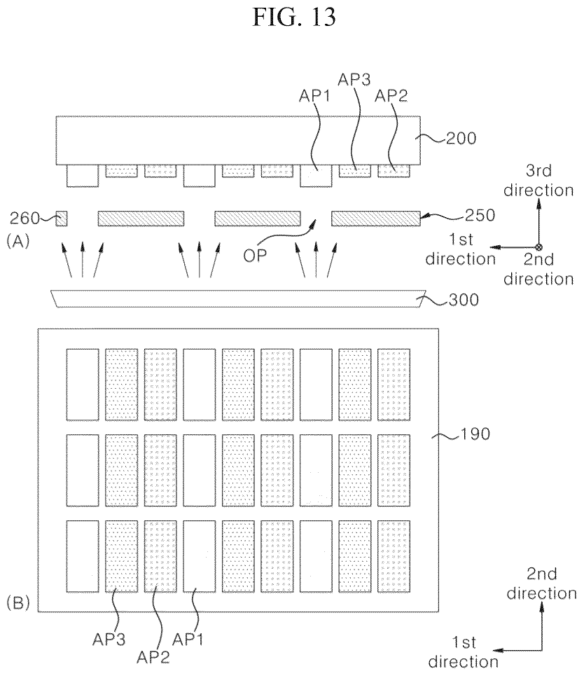

Referring to FIG. 13, the deposition mask 250 may be shifted to align the openings OP under regions of the first surface 200a of the protective layer 200 corresponding to or overlapping the first pixel region PX1 (e.g., the first light-emitting portion EL1).

Thereafter, the first acid-containing patterns AP1 may be formed on (e.g., formed directly thereon) the first surface 200a of the protective layer 200 by performing a process substantially the same as or similar to that described with reference to FIG. 10.

As illustrated in (B) of FIG. 13, in an embodiment, a plurality of the first acid-containing patterns AP2 may be formed along the second direction to form a first acid-containing pattern column on the protective layer 200. A plurality of the first acid-containing pattern columns may be formed along the first direction. For example, the first acid-containing pattern column may be formed between the second acid-containing pattern column and the third acid-containing pattern column.

As described above, the first acid-containing pattern AP1 may be formed to have a relatively large thickness and/or a high acid-component content.

As described above, in an embodiment, the deposition mask having the opening corresponding to each pixel region such as a fine metal mask (FMM) may be used to form the acid-containing patterns having differential compositions or differential thicknesses for each pixel region.

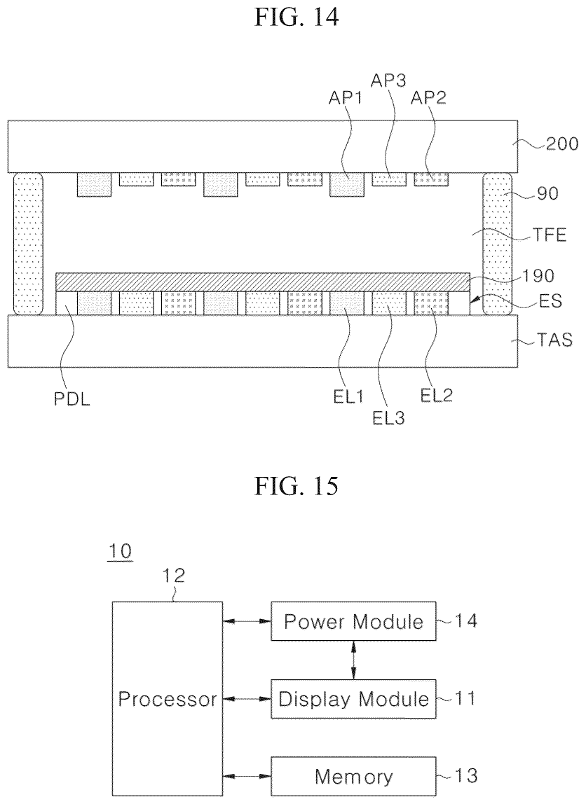

Referring to FIG. 14, in an embodiment, the protective layer 200 on which the acid-containing patterns AP1, AP2, and AP3 are formed may be combined or coupled with the transistor array structure TAS with the light-emitting structure ES interposed therebetween using the sealant 90 and the encapsulation layer TFE. According to some embodiments, the first to third acid-containing patterns AP1, AP2, and AP3 may be aligned to overlap the first to third light-emitting portions EL1, EL2, and EL3, respectively.

FIG. 15 is a block diagram of an electronic device according to an embodiment.

Referring to FIG. 15, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

In an embodiment, the power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

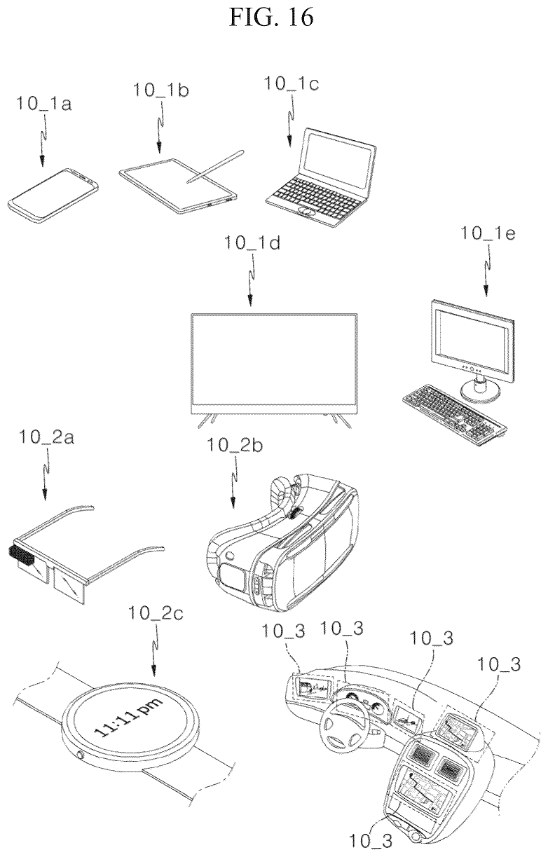

FIG. 16 is a schematic diagram of electronic devices according to some embodiments.

Referring to FIG. 16, non-limiting examples of various electronic devices to which the display device according to the above-described embodiments is applied include an electronic device for displaying an image such as a smartphone 10_1a, a tablet personal computer 10_1b, a laptop personal computer 10_1c, a television 10_1d, a desk monitor 10_1e, or the like; a wearable electronic device including a display module such as smart glasses 10_2a, a head mounted display 10_2b, a smart watch 10_2c, or the like; a vehicle electronic device 10_3 including a display module (e.g., a vehicle display) such as a center information display (CID) disposed at a vehicle instrument panel, a center fascia, a dashboard, etc., a head-up display, a room mirror display, or the like. The electronic device may include a virtual reality glass or an augmented reality glass. However, embodiments of the present disclosure are not necessarily limited thereto and the electronic device may be various other small-sized, medium-sized or large-sized electronic devices.

Hereinafter, Experimental Example including examples are presented to enhance understanding of embodiments of the present disclosure, but the present disclosure are not necessarily limited thereto. For example, is clear to those skilled in the art that various changes and modifications to the examples are possible within the scope of the present inventive concepts. These modifications and modifications fall within the scope of the attached claims.

### Reference Example

An ink for the hole injection layer HIL was coated on an ITO electrode using an inkjet printing, and then a hole injection layer was formed by drying and baking. An ink for the hole transport layer HTL was coated on the hole injection layer using an inkjet printing, and a hole transport layer was formed by drying and baking.

Quantum dot ink was formed using a quantum dot dispersion including each of a red quantum dot, a green quantum dot and a blue quantum dot. The quantum dot ink was coated using an inkjet printing, and a red emission layer, a green emission layer, and a blue emission layer were formed by drying and baking.

A ZnMgO layer as an electron transport layer and a ZnO layer as an electron injection layer were formed using an inkjet printing on each of the red, green and blue emission layers. An AgMg electrode was deposited on the electron injection layer to manufacture a red-light emitting device, a green light-emitting device and a blue light-emitting device.

### Example 1

Light-emitting devices having layers of the same materials and thickness as those of the light-emitting devices of Reference Example were manufactured, except that an acid-containing pattern including polyacrylic acid (PAA) with an acid unit content of 0.5 wt % was formed on the AgMg electrode of each of the red light-emitting device, the green light-emitting device and the blue light-emitting device.

### Example 2

The light-emitting devices having the same structure as that in Example 1 were manufactured, except that an acid-containing pattern including polyacrylic acid (PAA) with an acid unit content of 0.25 wt % was formed.

A current efficiency (cd/A) of each of the red light-emitting device, the green light-emitting device and the blue-light emitting device included in Example 1 and Example 2 was measured using a luminance meter CS-2000 (Konica Minolta). The measurement results are shown in Table 1 below.

TABLE 1

| Reference Example | | | Example 1 | | | Example 2 | | |
|---|---|---|---|---|---|---|---|---|
| red | green | blue | red | green | blue | red | green | blue |
| 1.4 | 8.9 | 0.25 | 3.8 | 28.4 | 1.6 | 3.1 | 21.6 | 0.9 |

Referring to Table 1, in Examples where the acid-containing pattern was formed, an overall current efficiency of red, green and blue light-emitting devices was increased compared to that from Reference Example.

Referring to Example 1 in which the acid-component content was increased compared to that of Example 2, the current efficiency increase ratio was significantly increased in the blue light-emitting device. In the green light-emitting device, the current efficiency was slightly increased as the acid-component content increased compared to that in the red light-emitting device.

From the results of Table 1, it is confirmed that the quantum efficiency/luminous efficiency can be further enhanced by increasing the thickness and/or the acid component content of the acid-containing pattern covering the blue light-emitting device.

What is claimed is:

1. A display device, comprising:
a base substrate;
a plurality of transistors arranged on the base substrate;
a plurality of pixel electrodes electrically connected to the plurality of transistors, respectively;
a plurality of light-emitting portions on the plurality of pixel electrodes, respectively;
a counter electrode covering the plurality of light-emitting portions; and
a plurality of acid-containing patterns disposed on the counter electrode and overlapping the plurality of light-emitting portions, respectively, the plurality of acid-containing patterns is spaced apart from each other.

2. The display device of claim 1, wherein:
the plurality of light-emitting portions includes quantum dots that emit different colors from each other.

3. The display device of claim 2, wherein:
the plurality of transistors includes first to third transistors;
the plurality of pixel electrodes includes first to third pixel electrodes;
the plurality of light-emitting portions includes first to third light-emitting portions;
the plurality of acid-containing patterns includes first to third acid-containing patterns,
wherein a thickness of the first acid-containing pattern is different from thicknesses of the second acid-containing pattern and the third acid-containing pattern; or
an acid component content of the first acid-containing pattern is different from acid component contents of the second acid-containing pattern and the third acid-containing pattern.

4. The display device of claim 3, wherein the first light-emitting portion, the second light-emitting portion and the third light-emitting portion include a blue light-emitting quantum dot, a green light-emitting quantum dot and a red light-emitting quantum dot, respectively.

5. The display device of claim 4, wherein the thickness of the first acid-containing pattern is greater than the thickness of each of the second acid-containing pattern and the third acid-containing pattern.

6. The display device of claim 5, wherein the thickness of the second acid-containing pattern is greater than the thickness of the third acid-containing pattern.

7. The display device of claim 4, wherein the acid component content included in the first acid-containing pattern is greater than the acid component content included in each of the second acid-containing pattern and the third acid-containing pattern.

8. The display device of claim 7, wherein the acid component content included in the second acid-containing pattern is greater than the acid component content included in the third acid-containing pattern.

9. The display device of claim 2, wherein:
each of the plurality of light-emitting portions includes an emission layer including the quantum dots, and an electron transport layer between the emission layer and the counter electrode; and
the electron transport layer includes metal oxide particles including zinc.

10. The display device of claim 1, wherein each of the plurality of acid-containing patterns includes an organic material including at least one group selected from a carboxyl group, a sulfonic acid group and a phosphonic acid group.

11. The display device of claim 1, wherein the plurality of acid-containing patterns is in direct contact with a top surface of the counter electrode.

12. The display device of claim 1, further comprising a protective layer stacked on the counter electrode,
wherein the plurality of acid-containing patterns is in direct contact with a bottom surface of the protective layer facing the counter electrode, and are spaced apart from the counter electrode in a thickness direction of the display device.

13. An electronic device, comprising:
a display device;
a memory; and
a processor executing data included in the memory to control an operation of the display device, the display device comprising:
a base substrate;
a plurality of transistors arranged on the base substrate;
a plurality of pixel electrodes electrically connected to the plurality of transistors, respectively;
a plurality of light-emitting portions on the plurality of pixel electrodes, respectively;
a counter electrode covering the plurality of light-emitting portions; and
a plurality of acid-containing patterns overlapping the plurality of light-emitting portions, respectively, and separated from each other on the counter electrode.

14. The electronic device of claim 13, wherein the electronic device includes virtual reality or augmented reality glasses, a smartphone, a tablet personal computer, a laptop personal computer, a television a desk monitor, smart glasses, a head mounted display, a smart watch, or a vehicle display.

15. A method of manufacturing a display device, comprising:
forming a transistor array structure comprising a plurality of transistors;
forming a plurality of pixel electrodes electrically connected to the plurality of transistors, respectively;
forming a plurality of light-emitting portions on the plurality of pixel electrodes, respectively;
forming a counter electrode covering the plurality of light-emitting portions;
forming acid-containing patterns using a deposition mask that includes openings corresponding to the plurality of light-emitting portions on the counter electrode or a protective layer; and
stacking the protective layer on the counter electrode with the acid-containing patterns interposed therebetween.

16. The method of claim 15, wherein forming of the acid-containing patterns comprises directly depositing an acid-containing material on the counter electrode.

17. The method of claim 15, wherein the forming of the acid-containing patterns comprises directly depositing an acid-containing material on the protective layer.

18. The method of claim 15, wherein the deposition mask includes a fine metal mask (FMM).

19. The method of claim 15, wherein:
the forming of the transistor array structure comprises forming first to third transistors;
the forming of the plurality of pixel electrodes comprises forming first to third pixel electrodes;
the forming of the plurality of light-emitting portions comprises forming first to third light-emitting portions;
the forming of the acid-containing patterns comprises forming a first acid-containing pattern, a second acid-containing pattern and a third acid-containing pattern overlapping the first light-emitting portion, the second light-emitting portion and the third light-emitting portion, respectively, the first to third acid-containing patterns are separated from each other; and
the first light-emitting portion, the second light-emitting portion and the third light-emitting portion include quantum dots that emit different colors from each other.

20. The method of claim 19, wherein the forming of the acid-containing patterns comprises forming the first acid-containing pattern, the second acid-containing pattern, and the third acid-containing pattern independently by shifting the deposition mask.
